(19) United States
(12) Patent Application Publication
(10) Pub. No.: US 2026/0214884 A1
(43) Pub. Date: Jul. 23, 2026

(54) SEMICONDUCTOR DEVICE

(71) Applicant: SAMSUNG ELECTRONICS CO., LTD., Suwon-si (KR)

(72) Inventors: Jinah KIM, Suwon-si (KR); Sangil Han, Suwon-si (KR); Yoonjae Kim, Suwon-si (KR); Seunguk Han, Suwon-si (KR); Jinwoo Han, Suwon-si (KR); Seongbin Hong, Suwon-si (KR)

(73) Assignee: SAMSUNG ELECTRONICS CO., LTD., Suwon-si (KR)

(21) Appl. No.: 19/450,131

(22) Filed: Jan. 15, 2026

(30) Foreign Application Priority Data
Jan. 20, 2025 (KR) 10-2025-0008176

(51) Int. Cl. H10B 12/00

(52) U.S. Cl. CPC H10B 12/30; H10B 12/03; H10B 12/05

(57) ABSTRACT

A semiconductor device may include: a substrate; a bit line extending in a vertical direction on the substrate; a transistor body portion connected to the bit line and including a first source/drain region, a channel region, and a second source/drain region, which are arranged in the order of the first source/drain region, the channel region, and the second source/drain region in a first horizontal direction; a word line extending in a second horizontal direction crossing the first horizontal direction, wherein the word line is on the channel region; a gate dielectric film between the channel region and the word line; a cell capacitor connected to the second source/drain region in the first horizontal direction and including a storage electrode, a capacitor dielectric film, and a plate electrode; and an etch stop layer between the word line and the capacitor dielectric film, the etch stop layer contacting the capacitor dielectric film.

### CROSS-REFERENCE TO RELATED APPLICATION

This application is based on and claims priority under 35 U.S.C. § 119 to Korean Patent Application No. 10-2025-0008176, filed on Jan. 20, 2025, in the Korean Intellectual Property Office, the disclosure of which is incorporated by reference herein in its entirety.

### BACKGROUND

### 1. Field

Some embodiments of the present disclosure relate to a semiconductor device, and more particularly, to a vertical semiconductor device having a three-dimensional structure.

### 2. Brief Description of Related Art

In order to have excellent performance and economic efficiency, it has been required to increase the integration of memory devices. In particular, the integration of memory devices is an important factor in determining the economic efficiency of a product. As the integration of two-dimensional memory devices is mainly determined by the area occupied by a unit memory cell, the integration of two-dimensional memory devices is greatly affected by the level of fine pattern formation technologies. However, as expensive equipment is needed for fine pattern formation and the area of a chip die is limited, the integration of two-dimensional memory devices is still constrained, even though the integration has increased. Accordingly, a vertical semiconductor device having a three-dimensional structure is needed.

### SUMMARY

According to some embodiments of the present disclosure, a vertical semiconductor device may be provided and have a three-dimensional structure, which may provide stable performance and improved reliability.

According to some embodiments of the present disclosure, a semiconductor device may be provided and include: a substrate; a bit line extending in a vertical direction on the substrate; a transistor body portion connected to the bit line and including a first source/drain region, a channel region, and a second source/drain region, which are arranged in the order of the first source/drain region, the channel region, and the second source/drain region in a first horizontal direction; a word line extending in a second horizontal direction crossing the first horizontal direction, wherein the word line is on the channel region; a gate dielectric film between the channel region and the word line; a cell capacitor connected to the second source/drain region in the first horizontal direction and including a storage electrode, a capacitor dielectric film, and a plate electrode; and an etch stop layer between the word line and the capacitor dielectric film, the etch stop layer contacting the capacitor dielectric film.

Technical aspects achieved by embodiments of the present disclosure are not limited to the above-described aspects, and other technical aspects that are not mentioned herein, that are achieved by embodiments of the present disclosure, would be clearly understood by a person skilled in the art from the description of the present disclosure.

According to some embodiments of the present disclosure, a semiconductor device may be provided and include: a bit line extending in a vertical direction on a substrate; a pair of transistor body portions connected to the bit line and including a first source/drain region, a channel region, and a second source/drain region, which are arranged in the order of the first source/drain region, the channel region, and the second source/drain region in a first horizontal direction; a pair of word lines extending in a second horizontal direction crossing the first horizontal direction, the pair of word lines being on the channel region between the pair of transistor body portions; a pair of gate dielectric films between the pair of transistor body portions and the pair of word lines; a cell capacitor connected to the second source/drain region in the first horizontal direction and including a storage electrode, a capacitor dielectric film, and a plate electrode; a liner insulating layer that is on the pair of transistor body portions and the capacitor dielectric film, and an etch stop layer that contacts the capacitor dielectric film.

According to some embodiments of the present disclosure, a semiconductor device may be provided and include: a substrate; a bit line extending in a vertical direction on the substrate; a transistor body portion connected to the bit line and including a first source/drain region, a channel region, and a second source/drain region, which are arranged in the order of the first source/drain region, the channel region, and the second source/drain region in a first horizontal direction; a word line extending in a second horizontal direction crossing the first horizontal direction, wherein the word line is on the channel region; a gate dielectric film between the channel region and the word line; a cell capacitor connected to the second source/drain region in the first horizontal direction, and including a storage electrode, a capacitor dielectric film, and a plate electrode; and at least one etch stop layer between the word line and the capacitor dielectric film and including an element having a concentration that gradually varies.

According to some embodiments of the present disclosure, a method of manufacturing a semiconductor device, the method including: forming a bit line on a substrate, the bit line extending in a vertical direction; forming a transistor body portion connected to the bit line, the transistor body portion including: a first source/drain region, a channel region, and a second source/drain region, which are arranged in the order of the first source/drain region, the channel region, and the second source/drain region in a first horizontal direction; forming a word line extending in a second horizontal direction crossing the first horizontal direction, wherein the word line is on the channel region; forming a gate dielectric film, wherein the gate dielectric film is between the channel region and the word line; forming a cell capacitor connected to the second source/drain region in the first horizontal direction, the cell capacitor including a storage electrode, a capacitor dielectric film, and a plate electrode; and forming an etch stop layer, the etch stop layer being between the word line and the capacitor dielectric film and contacting the capacitor dielectric film.

### BRIEF DESCRIPTION OF DRAWINGS

Embodiments will be more clearly understood from the following detailed description taken in conjunction with the accompanying drawings in which:

FIG. 1 is an equivalent circuit diagram illustrating a cell array of a semiconductor device according to an embodiment;

FIG. 2 is a cross-sectional view of a semiconductor device according to an embodiment;

FIG. 3 is an enlarged cross-sectional view of a region of FIG. 2;

FIGS. 4A, 4B, 4C, and 4D are schematic views illustrating various processes of forming an etch stop layer of FIG. 2;

FIGS. 5 to 7 are each an enlarged cross-sectional view illustrating a semiconductor device according to an embodiment;

FIGS. 8 to 25 are cross-sectional views for explaining a process order of a method of fabricating a semiconductor device, according to an embodiment; and

FIG. 26 is a configuration view illustrating a system including a semiconductor device according to an embodiment.

### DETAILED DESCRIPTION

Hereinafter, non-limiting example embodiments of the present disclosure are described in detail with reference to the accompanying drawings.

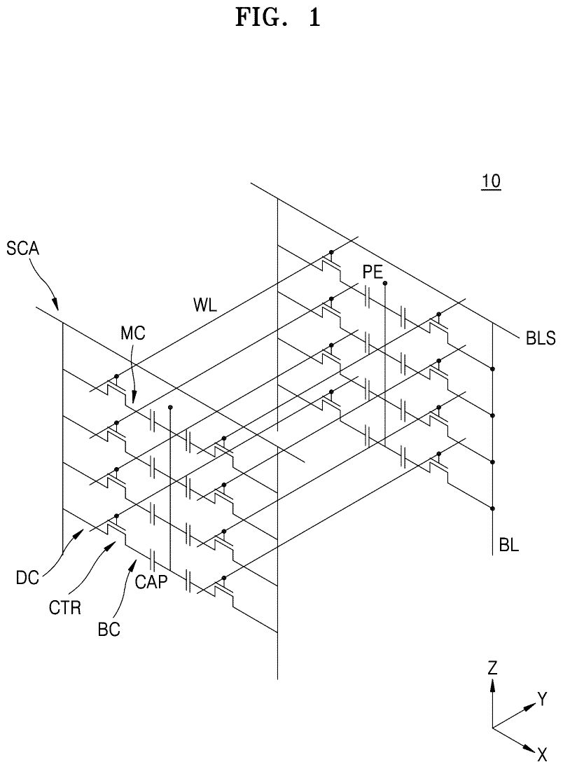

FIG. 1 is an equivalent circuit diagram illustrating a cell array of a semiconductor device 10 according to an embodiment.

Referring to FIG. 1, the semiconductor device 10 according to an embodiment may include a plurality of memory cells MC, each memory cell MC including a cell transistor CTR and a cell capacitor CAP, which may be arranged in a vertical direction Z and connected to each other.

The plurality of memory cells MC may be spaced apart from each other in each of a first horizontal direction X and the vertical direction Z and arranged in columns forming a sub-cell array SCA. Furthermore, in the semiconductor device 10, a plurality of sub-cell arrays SCA may be spaced apart from each other in a second horizontal direction Y crossing the first horizontal direction X.

A plurality of word lines WL may extend in the second horizontal direction Y, and may be spaced apart from each other in the first horizontal direction X and the vertical direction Z. A plurality of bit lines BL may extend in the vertical direction Z, and may be spaced apart from each other in the first horizontal direction X and the second horizontal direction Y.

In some embodiments, some of the plurality of bit lines BL may be connected to each other by a bit-line strapping line BLS extending in the first horizontal direction X. For example, the bit-line strapping line BLS may connect the bit lines BL arranged in the first horizontal direction X among the plurality of bit lines BL.

The plurality of cell capacitors CAP may be commonly connected to a plurality of plate electrodes PE extending in the second horizontal direction Y and the vertical direction Z. Although the plurality of plate electrodes PE are illustrated in the drawing as extending in the vertical direction Z, the plurality of plate electrodes PE arranged in the second horizontal direction Y may be integrally formed.

The cell capacitor CAP and the cell transistor CTR arranged in the first horizontal direction X may be arranged in mirror-image symmetry with respect to a virtual plane extending in the second horizontal direction Y and the vertical direction Z where the plurality of plate electrodes PE are arranged.

The cell transistor CTR may be connected to the bit line BL through a direct contact DC, and the cell transistor CTR may be connected to the cell capacitor CAP through a buried contact BC. However, the direct contact DC and/or the buried contact BC may be omitted or substituted.

Hereinafter, the semiconductor device 10 according to an embodiment is described in detail.

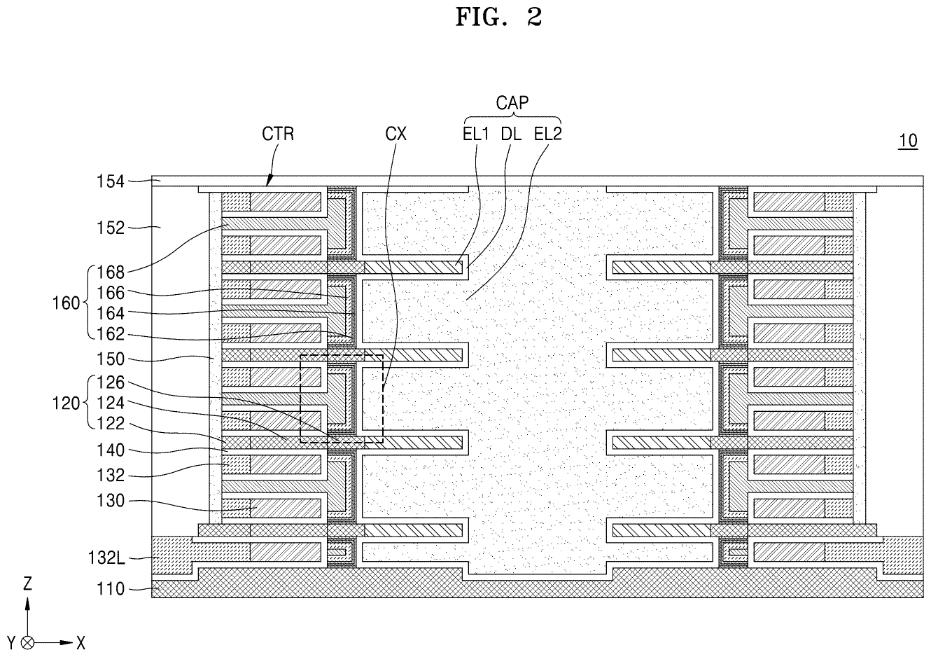

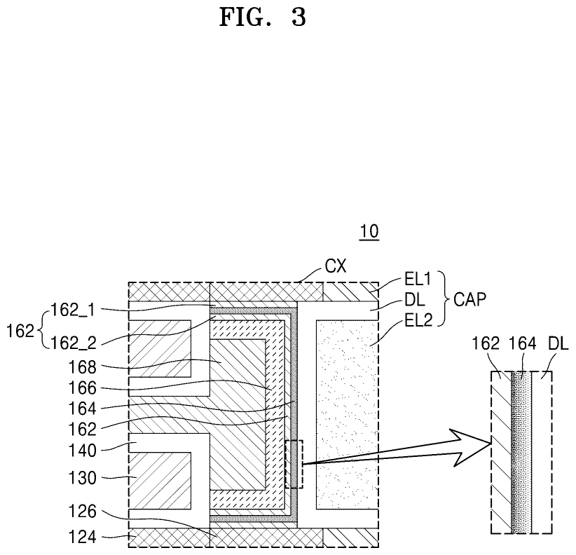

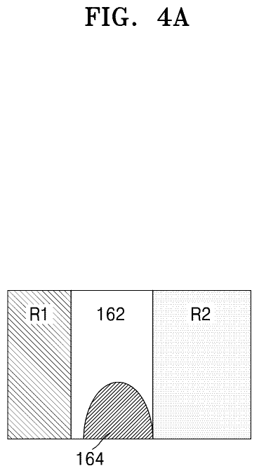

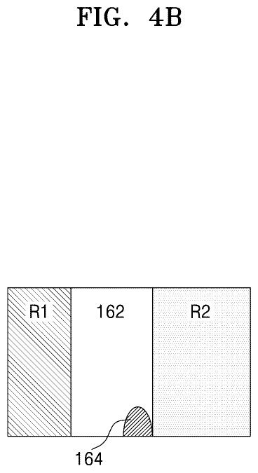

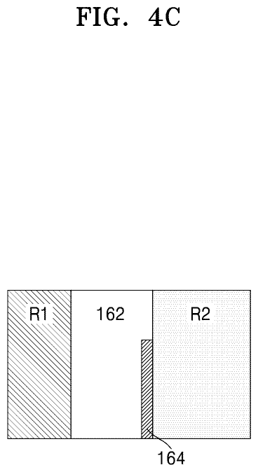

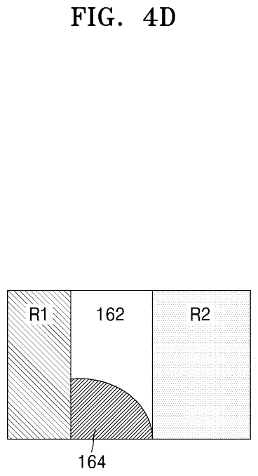

FIG. 2 is a cross-sectional view of the semiconductor device 10 according to an embodiment. FIG. 3 is an enlarged cross-sectional view of a region CX of FIG. 2. FIGS. 4A to 4D are schematic views illustrating various processes of forming an etch stop layer 164 of FIG. 2.

Referring to FIGS. 2 to 4 together, the semiconductor device 10 may include the plurality of cell transistors CTR and the plurality of cell capacitors CAP which may be arranged on a substrate 110.

Each of the plurality of cell transistors CTR may include a transistor body portion 120, a word line 130, a gate dielectric film 140, and a bit line 150. Each of the plurality of cell capacitors CAP may include a first electrode EL1, a second electrode EL2, and a capacitor dielectric film DL.

The substrate 110 may include a semiconductor material. For example, the substrate 110 may include a semiconductor material, such as silicon (Si) or germanium (Ge). In some embodiments, the substrate 110 may include a silicon-on-insulator (SOI) or a germanium-on-insulator (GeOI).

According to some embodiments, a peripheral circuit and a wiring layer connected to the peripheral circuit may be formed in a partial area of the substrate 110. For example, the peripheral circuit may include a planar metal-oxide-semiconductor field-effect transistor (MOSFET) forming a sub-word line driver, a sense amplifier, or the like, but embodiments of the present disclosure are not limited thereto. Furthermore, a lower insulating layer may be formed on the substrate 110 to cover the peripheral circuit and the wiring layer.

A plurality of transistor body portions 120 may extend in the first horizontal direction X over the substrate 110 and may be spaced apart from each other in the vertical direction Z. The plurality of transistor body portions 120 may be formed of, for example, an undoped semiconductor material or a doped semiconductor material. In some embodiments, each of the plurality of transistor body portions 120 may be formed of single crystal silicon or polysilicon. In some other embodiments, the plurality of transistor body portions 120 may include amorphous metal oxide, polycrystalline metal oxide, a combination of amorphous metal oxide and polycrystalline metal oxide, or the like, for example, at least one from among In—Ga based oxide (IGO), In—Zn based oxide (IZO), and In—Ga—Zn based oxide (IGZO).

The plurality of transistor body portions 120 may include a first source/drain region 122, a single crystal channel layer 124, and a second source/drain region 126, which may be arranged in order in the first horizontal direction X. For example, the first source/drain region 122 may be connected to the bit line 150, and the second source/drain region 126 may be connected to the first electrode EL1 of the cell capacitor CAP. The first source/drain region 122 and the second source/drain region 126 may include a semiconductor material doped with impurities at a high concentration.

A plurality of word lines 130 may be arranged adjacent to the plurality of transistor body portions 120 and extend in the second horizontal direction Y. In some embodiments, the semiconductor device 10 may have a dual gate transistor structure, and each of the plurality of word lines 130 may be arranged on the upper surfaces and bottom surfaces of the plurality of transistor body portions 120. In some other embodiments, each of the plurality of word lines 130 may have a gate all around structure entirely surrounding the plurality of transistor body portions 120.

In some embodiments, the plurality of word lines 130 may include or consist of a conductive barrier film and a conductive charge layer covering the conductive barrier film. The conductive barrier film may include, for example, metal, conductive metal nitride, conductive metal silicide, or a combination thereof. For example, the conductive barrier film may be formed of titanium nitride (TiN). The conductive charge layer may include, for example, doped silicon, Ru, RuO, Pt, PtO, Ir, IrO, SrRuO (SRO), CaRuO (CRO), BaRuO, La(Sr, Co)O, Ti, TiN, W, WN, Ta, TaN, TiAlN, TiSiN, TaAlN, TaSiN, or a combination thereof. In some embodiments, the conductive charge layer may include tungsten (W).

At least one spacer 132 may be arranged between a plurality of bit lines 150 and the word line 130 adjacent thereto. The spacer 132 may be arranged at the same vertical level as a vertical level of the word line 130, one side wall of the spacer 132 may be in contact with the word line 130, and the opposite side wall of the spacer 132 may be in contact with the bit line 150.

A lowermost one of the spacers 132 that is in contact with the word line 130 may extend over an upper surface of the substrate 110 to have a thickness greater than a thickness of other ones of the spacers 132. The spacer 132 extending over the upper surface of the substrate 110 may be referred to as a bottom spacer 132L. The spacers 132, including the bottom spacer 132L, may each include silicon nitride, silicon oxynitride, or silicon oxide.

The gate dielectric film 140 may be provided between the word line 130 and the transistor body portion 120. For example, the gate dielectric film 140 may conformally cover an upper surface, a bottom surface, and a side surface of each of the plurality of word lines 130.

In some embodiments, the gate dielectric film 140 may include at least one selected from among silicon oxide, a high-k dielectric material having a dielectric constant greater than that of the silicon oxide, and a ferroelectric material. The gate dielectric film 140 may include, for example, a material selected from among hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAlO), zirconium oxide (ZrO), zirconium silicate (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO).

A separation insulating layer 160 may be arranged between the plurality of transistor body portions 120. The separation insulating layer 160 may electrically separate a pair of word lines 130 arranged between a pair of transistor body portions 120 facing each other in the vertical direction Z. In detail, the separation insulating layer 160 may include a liner insulating layer 162, the etch stop layer 164, a spacer liner layer 166, and a spacer embedded layer 168. Detailed descriptions thereon are presented below.

The plurality of bit lines 150 may extend in the vertical direction Z over the substrate 110, and may be spaced apart from each other in the second horizontal direction Y. The plurality of bit lines 150 may be one from among: a doped semiconductor material, such as impurity-doped silicon, impurity-doped germanium, etc.; conductive metal nitride, such as titanium nitride, tantalum nitride, etc.; metal, such as tungsten, titanium, tantalum, etc.; and a metal/semiconductor compound, such as tungsten silicide, cobalt silicide, titanium silicide, etc.

A bit-line insulating layer 152 may extend in the vertical direction Z around the bit line 150. The bottom surface of the bit-line insulating layer 152 may be in contact with the upper surface of the bottom spacer 132L. Furthermore, a cover insulating layer 154 may be arranged over the bit-line insulating layer 152 to cover all of the plurality of cell transistors CTR and the plurality of cell capacitors CAP.

The cell capacitor CAP may include the first electrode EL1, the second electrode EL2, and the capacitor dielectric film DL. The first electrode EL1 may be connected to the second source/drain region 126 and may have a shape extending in the first horizontal direction X. The capacitor dielectric film DL may be arranged to conformally cover a surface of the first electrode EL1. The second electrode EL2 may be arranged on the capacitor dielectric film DL to cover the first electrode EL1.

In some embodiments, the first electrode EL1 and the second electrode EL2 may each include: a doped semiconductor material; conductive metal nitride, such as titanium nitride, tantalum nitride, niobium nitride, tungsten nitride, etc.; metal, such as tungsten, ruthenium, iridium, titanium, tantalum, etc.; conductive metal oxide, such as iridium oxide, niobium oxide, etc.

In the semiconductor device 10 according to an embodiment, the etch stop layer 164 may be injected between the word line 130 and the capacitor dielectric film DL. In the present disclosure, the etch stop layer 164 that is “injected” may mean a material layer that is formed by an injection process, not a deposition process. As described below, the etch stop layer 164 may be formed by a method of forming the liner insulating layer 162 and then injecting nitrogen into the liner insulating layer 162.

For reference, FIGS. 4A to 4D schematically illustrate various methods of injecting nitrogen. In other words, the liner insulating layer 162 may be arranged between a first region R1 and a second region R2. As an injection process for forming the etch stop layer 164, any one process selected from among a mixed growth process, an annealing process, and a plasma process may be used.

In detail, FIG. 4A illustrates a mixed growth process using a mixed gas of NO/O₂. In this case, the etch stop layer 164 may be formed in the liner insulating layer 162 by growing in an oval shape at a center portion of the liner insulating layer 162. FIG. 4B illustrates an annealing process using an N₂O gas atmosphere. In this case, the etch stop layer 164 may be formed in the liner insulating layer 162 by growing in an overall shape with a bias towards the second region R2. FIG. 4C illustrates an annealing process using an NO gas atmosphere. In this case, the etch stop layer 164 may be formed in the liner insulating layer 162 by growing in a rectangular shape with a bias towards the second region R2. FIG. 4D illustrates a nitride process using plasma. In this case, the etch stop layer 164 may be formed in the liner insulating layer 162 by growing in a circular shape with a bias towards the first region R1. However, the injection process for forming the etch stop layer 164 is not limited to the processes described above.

According to these processes, the liner insulating layer 162 may include silicon oxide, and the etch stop layer 164 may include silicon nitride. In other words, the materials forming the liner insulating layer 162 and the etch stop layer 164 may be different from each other, and a material forming the etch stop layer 164 may have etching selectivity with respect to the liner insulating layer 162. Furthermore, in the silicon nitride forming the etch stop layer 164, the concentration of nitrogen may be gradually varied, which is based on the characteristics of injection processes.

Accordingly, in the semiconductor device 10 according to an embodiment, the liner insulating layer 162 may be arranged to come in contact with the transistor body portion 120, and the etch stop layer 164 may be spaced apart from the transistor body portion 120. In other words, the transistor body portion 120 may not be in contact with silicon nitride. The transistor body portion 120 may include the single crystal channel layer 124 including high purity silicon (Si), and the characteristics of the single crystal channel layer 124 may affect the characteristics of the cell transistor CTR. Accordingly, the etch stop layer 164 including silicon nitride may be apart from the transistor body portion 120 by the liner insulating layer 162 therebetween. The liner insulating layer 162 may include a first liner insulating layer 162_1 and a second liner insulating layer 162_2 depending on the arrangement location. A part of the etch stop layer 164 may be in contact with the first liner insulating layer 162_1, another part of the etch stop layer 164 may be in contact with the second liner insulating layer 162_2, and another part of the etch stop layer 164 may be in contact with the capacitor dielectric film DL. In other words, the capacitor dielectric film DL may be conformally arranged along the first electrode EL1, the etch stop layer 164, and the first liner insulating layer 162_1.

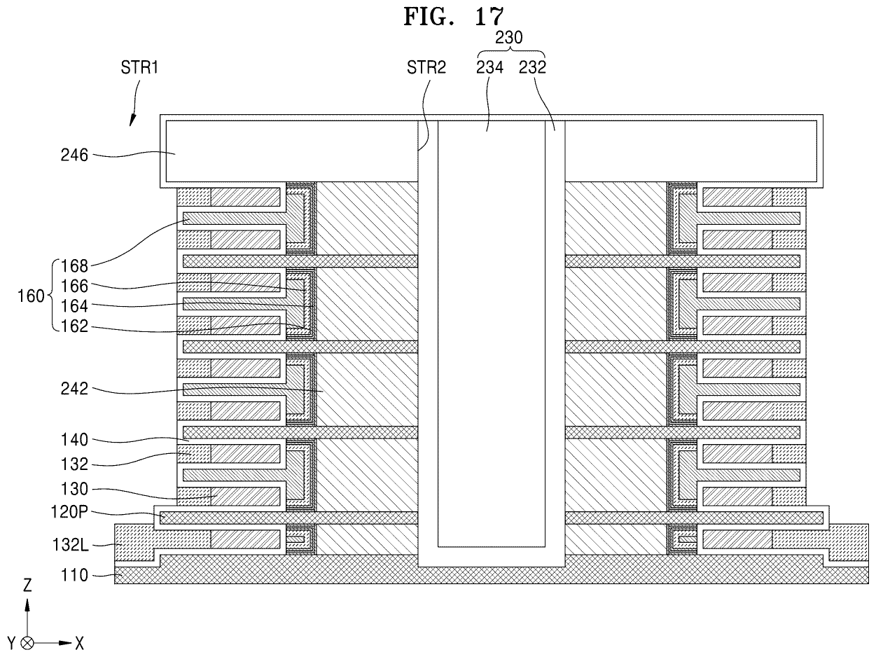

In other words, in the semiconductor device 10 according to an embodiment, the etch stop layer 164 may be formed in contact with the capacitor dielectric film DL without contact with the transistor body portion 120. In some embodiments, the etch stop layer 164 may be arranged lengthwise at least in the vertical direction Z between a pair of the transistor body portions 120 facing each other in the vertical direction Z. As described below, the etch stop layer 164 may stop etching, without any etching deviation between upper and lower parts of the support sacrificial layer 242, in an etching process of a support sacrificial layer 242 (see FIG. 17). Accordingly, as the upper and lower parts of the support sacrificial layer 242 are all etched in without any deviation, space for forming the height of the cell capacitor CAP at its maximum may be provided. Accordingly, the etch stop layer 164 may be disposed to face the transistor body portion 120 in the vertical direction Z without making contact therewith, and the etch stop layer 164 may be in contact with the capacitor dielectric film DL in the first horizontal direction X while facing each other.

In the semiconductor device 10 according to an embodiment, the etch stop layer 164 may be formed to contact both of a pair of the gate dielectric films 140 corresponding to a pair of word lines 130 placed between a pair of transistor body portions 120. In other words, the etch stop layer 164 may have a U shape rotated by 90°. The etch stop layer 164 may be formed to overlap with the second source/drain region 126 of the transistor body portion 120 in the vertical direction Z. Furthermore, the liner insulating layer 162 may be formed to contact each of the transistor body portion 120, the etch stop layer 164, the capacitor dielectric film DL, and the gate dielectric film 140. Accordingly, the side wall of the liner insulating layer 162 in contact with the capacitor dielectric film DL and the side wall of the etch stop layer 164 in contact with the capacitor dielectric film DL may be coplanar with each other in the vertical direction Z.

In order to satisfy excellent performance and economic efficiency, the integration of memory devices may be increased. In particular, the integration of memory devices is an important factor in determining the economic efficiency of a product. As the integration of two-dimensional memory devices is mainly determined by the area occupied by a unit memory cell, the integration of two-dimensional memory devices is greatly affected by the level of fine pattern formation technologies. However, as expensive equipment is required for fine pattern formation and the area of a chip die is limited, it is still constrained although the integration of two-dimensional memory devices has increased. Accordingly, there is a demand for vertical semiconductor devices having a three-dimensional structure.

However, during a process of fabricating a vertical semiconductor device having a three-dimensional structure of a comparative embodiment, a deviation between the upper and lower parts of a support sacrificial layer may be generated according to the vertical direction Z in the etching process of the support sacrificial layer. Accordingly, considering the deviation, it is practical that an etching process is performed to have a portion left without completely removing the support sacrificial layer. This may cause a problem that the height of the cell capacitor is not formed at its maximum due to the characteristics of a fabricating process in which the cell capacitor is formed in the space where the support sacrificial layer is removed, in the first horizontal direction X or the second horizontal direction Y.

To address the above problem, in the semiconductor device 10 according to an embodiment, by forming the etch stop layer 164 injected between the word line 130 and the capacitor dielectric film DL, the deviation between the upper and lower parts of the support sacrificial layer 242 in the etching process may be reduced, the height of the cell capacitor CAP may be formed at its maximum in the first horizontal direction X or the second horizontal direction Y, thereby providing stable performance and improved reliability.

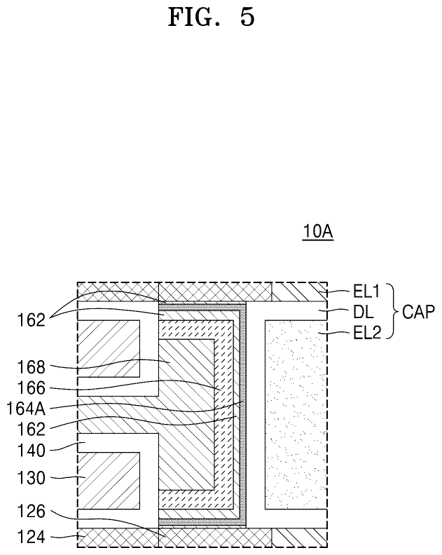

FIGS. 5 to 7 are each an enlarged cross-sectional view illustrating a semiconductor device according to an embodiment. In detail, FIGS. 5 to 7 each illustrate an area corresponding to the region CX of FIG. 2.

Most components forming semiconductor devices 10A, 10B, and 10C described below and materials forming the components are substantially identical or similar to those described above with reference to FIGS. 2 to 4D. Accordingly, for convenience of explanation, the differences from the semiconductor device 10 described above are mainly discussed.

Referring to FIG. 5, the semiconductor device 10A may include an etch stop layer 164A formed relatively close to the transistor body portion 120.

In the semiconductor device 10A according to an embodiment, by utilizing the characteristics of the injection process, the etch stop layer 164A may be formed relatively close to the transistor body portion 120. Even in this case, the transistor body portion 120 and the etch stop layer 164A may be formed to avoid contact with each other.

In the semiconductor device 10A according to an embodiment, the etch stop layer 164A may have a U shape rotated by 90°. The etch stop layer 164A may be formed to overlap with the second source/drain region 126 of the transistor body portion 120 in the vertical direction Z.

In the semiconductor device 10A according to an embodiment, the liner insulating layer 162 may be formed to contact each of the transistor body portion 120, the etch stop layer 164A, the capacitor dielectric film DL, and the gate dielectric film 140. Accordingly, the side wall of the liner insulating layer 162 in contact with the capacitor dielectric film DL and the side wall of the etch stop layer 164A in contact with the capacitor dielectric film DL may be coplanar with each other in the vertical direction Z.

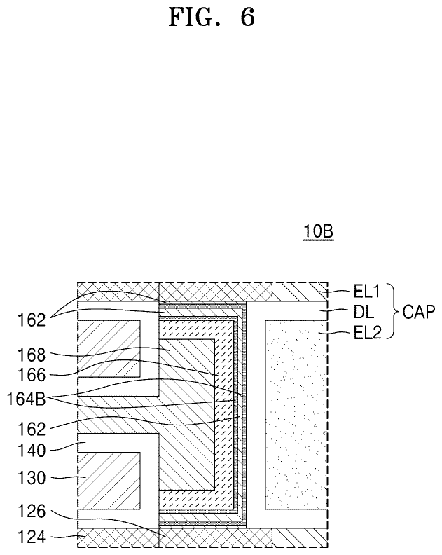

Referring to FIG. 6, the semiconductor device 10B may include a plurality of etch stop layers 164B.

In the semiconductor device 10B according to an embodiment, by utilizing the characteristics of the injection process, the etch stop layers 164B may be formed relatively close to the transistor body portion 120, and then, the etch stop layers 164B may be formed relatively close to the spacer liner layer 166. Even in this case, the transistor body portion 120 and the etch stop layers 164B may be formed to avoid contact with each other.

In the semiconductor device 10B according to an embodiment, the etch stop layers 164B may be formed in a pair each having a U shape rotated by 90°. The etch stop layers 164B may be formed to overlap with the second source/drain region 126 of the transistor body portion 120 in the vertical direction Z.

In the semiconductor device 10B according to an embodiment, the liner insulating layer 162 may be formed to contact each of the transistor body portion 120, the etch stop layers 164B, the capacitor dielectric film DL, and the gate dielectric film 140. Accordingly, the side wall of the liner insulating layer 162 in contact with the capacitor dielectric film DL and the side wall of one of the etch stop layers 164B in contact with the capacitor dielectric film DL may be coplanar with each other in the vertical direction Z.

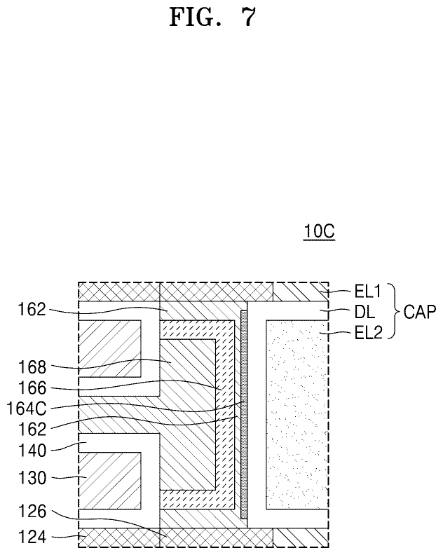

Referring to FIG. 7, the semiconductor device 10C may include an etch stop layer 164C having a straight line shape.

In the semiconductor device 10C according to an embodiment, by utilizing the characteristics of the injection process, the etch stop layer 164C may be formed in a straight line shape only in an area in contact with the capacitor dielectric film DL. Even in this case, the transistor body portion 120 and the etch stop layer 164C may not be in contact with each other.

In the semiconductor device 10C according to an embodiment, the etch stop layer 164C may have a straight line shape extending lengthwise in the vertical direction Z. The etch stop layer 164C may be formed to overlap with the second source/drain region 126 of the transistor body portion 120 in the vertical direction Z.

In the semiconductor device 10C according to an embodiment, the liner insulating layer 162 may be in contact with each of the transistor body portion 120, the etch stop layer 164C, the capacitor dielectric film DL, and the gate dielectric film 140. Accordingly, the side wall of the liner insulating layer 162 in contact with the capacitor dielectric film DL and the side wall of the etch stop layer 164C in contact with the capacitor dielectric film DL may be coplanar with each other in the vertical direction Z.

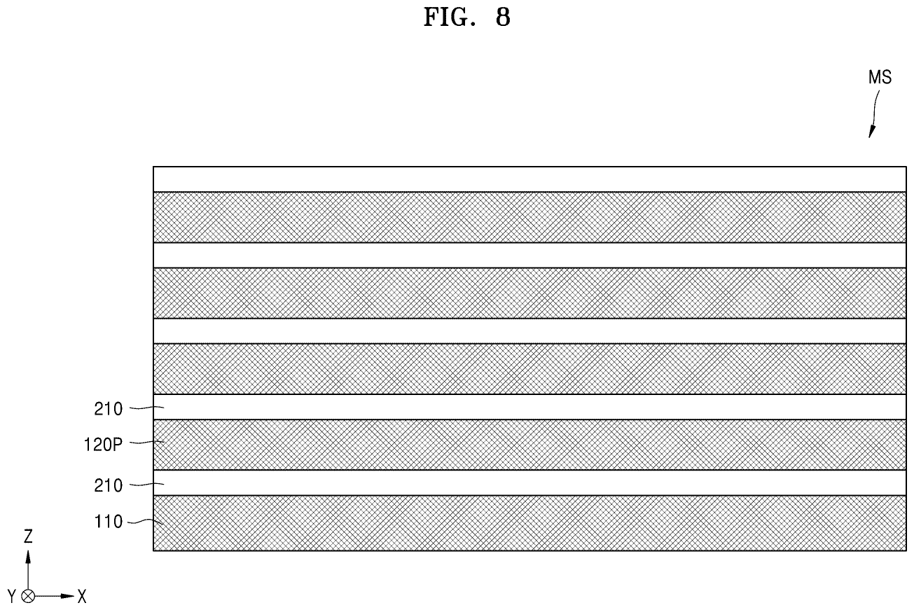

FIGS. 8 to 25 are cross-sectional views illustrating a process order for explaining a method of fabricating a semiconductor device, according to an embodiment.

According to some embodiments of the present disclosure, the specific process order may be performed differently from the described order. For example, two processes described sequentially may be performed substantially simultaneously, or may be performed in the reverse order of the order described.

Referring to FIG. 8, a stack structure MS, in which a plurality of mold sacrificial layers 210 and a plurality of single crystal semiconductor layers 120P are alternately stacked one by one, may be formed on the substrate 110.

The substrate 110 may include a single crystal semiconductor material. For example, the substrate 110 may include a semiconductor material, such as silicon (Si) or germanium (Ge).

Each of the plurality of mold sacrificial layers 210 and each of the plurality of single crystal semiconductor layers 120P may include a single crystal semiconductor material. Each of the plurality of mold sacrificial layers 210 may include a semiconductor material having etching selectivity with respect to each of the plurality of single crystal semiconductor layers 120P. In some embodiments, each of the plurality of mold sacrificial layers 210 may have etching selectivity with respect to the substrate 110. In some embodiments, each of the plurality of single crystal semiconductor layers 120P may include a material having etching characteristics that are identical or similar to those of the substrate 110.

In some embodiments, each of the plurality of mold sacrificial layers 210 may include silicon germanium (SiGe), and each of the plurality of single crystal semiconductor layers 120P may include silicon (Si). In some other embodiments, each of the plurality of single crystal semiconductor layers 120P may include a single crystal two-dimensional (2D) semiconductor material or a single crystal oxide semiconductor material. For example, each of the plurality of single crystal semiconductor layers 120P may include a single layer or multilayer of the single crystal oxide semiconductor material. In some embodiments, each of the plurality of single crystal semiconductor layers 120P may include a material having bandgap energy greater than a bandgap energy of silicon (Si).

Each of the plurality of mold sacrificial layers 210 and each of the plurality of single crystal semiconductor layers 120P may be formed by a deposition process, such as a chemical vapor deposition (CVD), plasma enhanced CVD (PECVD), or atomic layer deposition (ALD) process. In some embodiments, each of the plurality of mold sacrificial layers 210 and each of the plurality of single crystal semiconductor layers 120P may be formed in a single crystal state by using a lower layer in contact therewith as a seed layer, or in a single crystal state through heat treatment process.

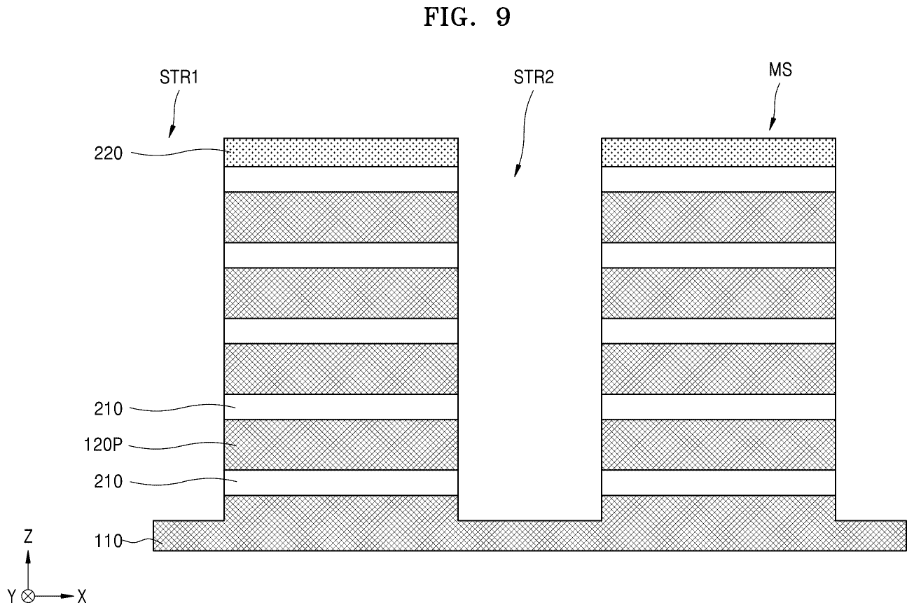

Referring to FIG. 9, in the resultant product of FIG. 8, a mask pattern layer 220 may be formed on the stack structure MS, and a first recess STR1 and a second recess STR2, which expose the substrate 110 by penetrating the stack structure MS, may be formed by using the mask pattern layer 220 as an etch mask. The mask pattern layer 220 may have a plurality of openings corresponding to the first recess STR1 and the second recess STR2.

The second recess STR2 may have an oval planar shape having the major axis in a first horizontal direction X and the minor axis in a second horizontal direction Y, or a rectangular planar shape with rounded corners which has the major axis in the first horizontal direction X and the minor axis in the second horizontal direction Y. In some embodiments, the first recess STR1 may have planar shape, such as a circle, an oval, a square with rounded corners, or a rectangle with rounded corners.

The first recess STR1 and the second recess STR2 may be spaced apart from each other in the first horizontal direction X. In some embodiments, the first recess STR1 may be arranged on each of the opposite sides of the second recess STR2 in the first horizontal direction X.

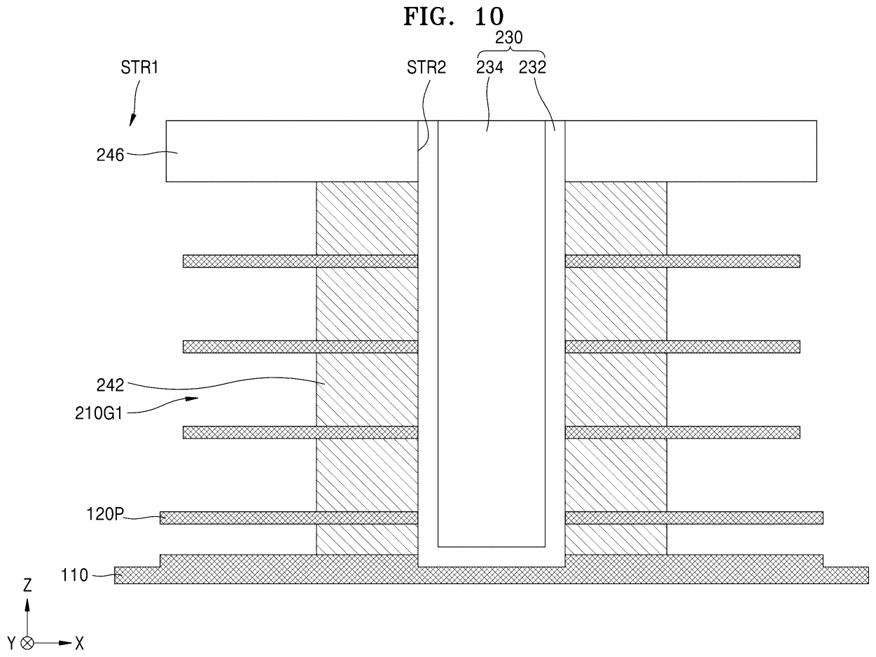

Referring to FIG. 10, in the resultant product of FIG. 9, after an embedded structure 230 that fills the second recess STR2 is formed, the mask pattern layer 220 may be removed.

By removing the plurality of mold sacrificial layers 210 through the first recess STR1 and the second recess STR2, a plurality of gaps may be formed between the plurality of single crystal semiconductor layers 120P. The plurality of gaps may be formed by removing the plurality of mold sacrificial layers 210 through an isotropic etching process having etching selectivity with respect to the substrate 110, the plurality of single crystal semiconductor layers 120P, and a liner layer 232.

In some embodiments, the isotropic etching process may be performed to expand the plurality of gaps by removing portions of the plurality of single crystal semiconductor layers 120P. Accordingly, the horizontal width and the vertical thickness of each of the plurality of single crystal semiconductor layers 120P may be reduced.

Next, the plurality of support sacrificial layers 242 may be formed to cover the surfaces of the plurality of single crystal semiconductor layers 120P. The plurality of support sacrificial layers 242 may be formed to completely fill the plurality of gaps. An upper insulating layer 246 may be formed on the uppermost one of the support sacrificial layers 242. The upper insulating layer 246 may include silicon oxide, and may be arranged at the same vertical level as a vertical level the upper surface of the embedded structure 230.

Next, by removing a portion of the support sacrificial layers 242, the width of the support sacrificial layers 242 in the first horizontal direction X may be less than the width of each of the plurality of single crystal semiconductor layers 120P in the first horizontal direction X. Accordingly, a plurality of first gaps 210G1 may be formed. For example, the process of removing a portion of the support sacrificial layers 242 may be performed by a wet etching process using a chemical etchant, but embodiments of the present disclosure are not limited thereto.

As the plurality of first gaps 210G1 are formed by removing portions of the plurality of support sacrificial layers 242, the portions of the plurality of single crystal semiconductor layers 120P may be arranged to protrude outwards from the plurality of support sacrificial layers 242.

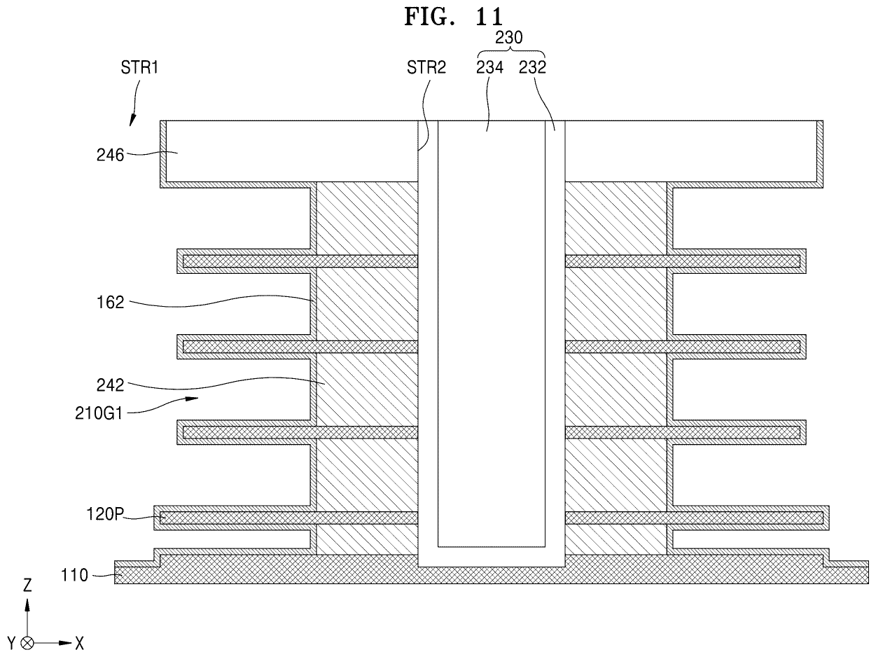

Referring to FIG. 11, the liner insulating layer 162 may be conformally formed on the exposed surfaces of the resultant product of FIG. 10.

The liner insulating layer 162 may be conformally formed to surround (e.g., at least partially surround) each of the plurality of single crystal semiconductor layers 120P exposed by the plurality of first gaps 210G1. In other words, the liner insulating layer 162 may protect the exposed surfaces of the plurality of single crystal semiconductor layers 120P. In some embodiments, the liner insulating layer 162 may include silicon oxide.

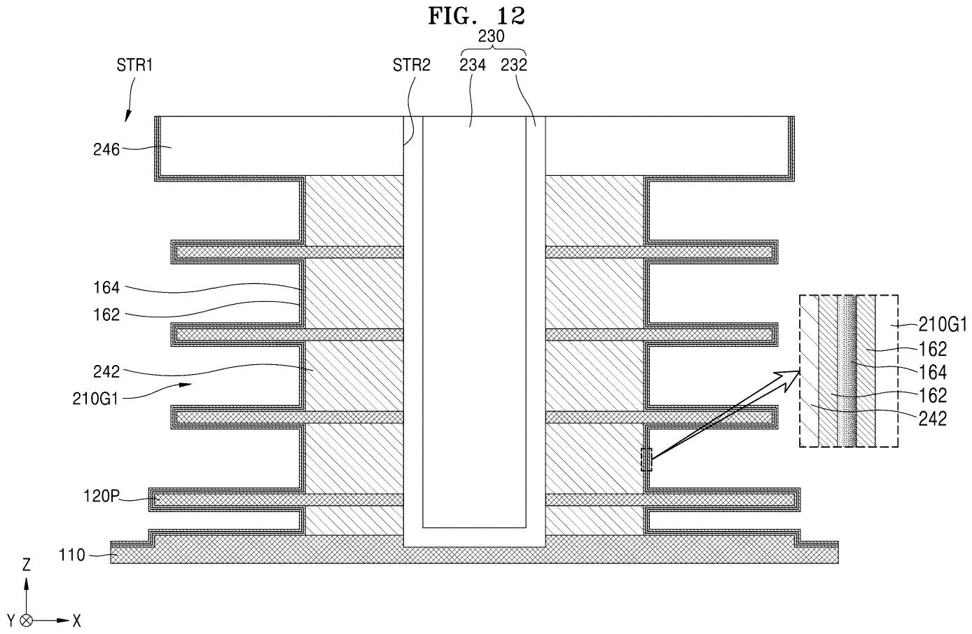

Referring to FIG. 12, in the resultant product of FIG. 11, the etch stop layer 164 may be formed in the liner insulating layer 162 by using an injection process.

As the etch stop layer 164 is formed by an injection process, not a deposition process, as described above, the etch stop layer 164 may be referred to as the injected etch stop layer. In other words, the etch stop layer 164 (i.e., the injected etch stop layer) may be formed by injecting nitrogen into the liner insulating layer 162. In some embodiments, as an injection process for forming the etch stop layer 164, any one process selected from among a mixed growth process, an annealing process, and a plasma process may be used.

Accordingly, the etch stop layer 164, in which the concentration of nitrogen gradually varies, may be formed in the center area of the liner insulating layer 162. The etch stop layer 164 may include silicon nitride, and may be formed not to contact the plurality of single crystal semiconductor layers 120P and the plurality of support sacrificial layers 242.

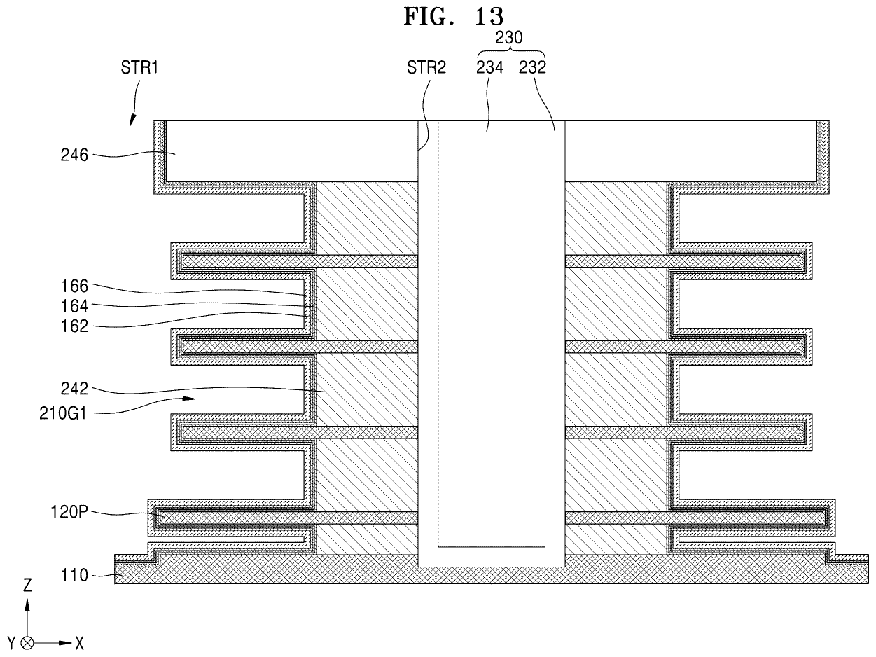

Referring to FIG. 13, the spacer liner layer 166 may be conformally formed on the exposed surface of the resultant product of FIG. 12.

The spacer liner layer 166 may be conformally formed to entirely surround the exposed surface of the liner insulating layer 162. In other words, the spacer liner layer 166 may protect the exposed surface of the liner insulating layer 162. In some embodiments, the spacer liner layer 166 may include silicon nitride. The spacer liner layer 166 may be formed to be thicker than the liner insulating layer 162, but embodiments of the present disclosure are not limited thereto.

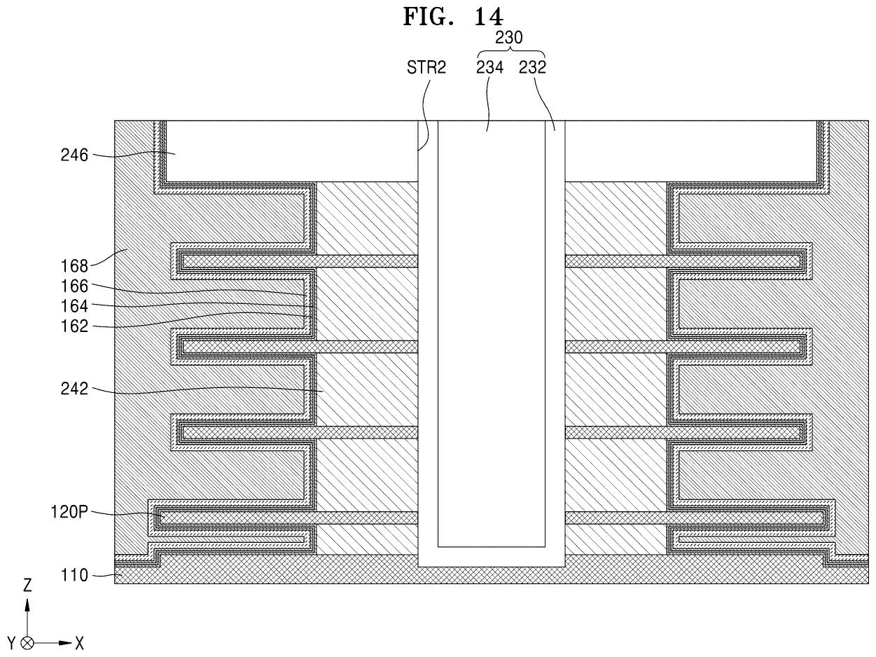

Referring to FIG. 14, in the resultant product of FIG. 13, the spacer embedded layer 168 may be formed to fill all of the plurality of first gaps 210G1.

In some embodiments, the spacer embedded layer 168 may be formed to entirely fill the first recess STR1 on each of the opposite sides of the second recess STR2. The upper surface of the spacer embedded layer 168 may be arranged at the same vertical level as a vertical level of the upper surface of the embedded structure 230.

In some embodiments, the spacer embedded layer 168 may include any one selected from among a silicon oxide film, a silicon oxynitride film, a carbon-containing silicon oxide film, a carbon-containing silicon nitride film, and a carbon-containing silicon oxynitride film.

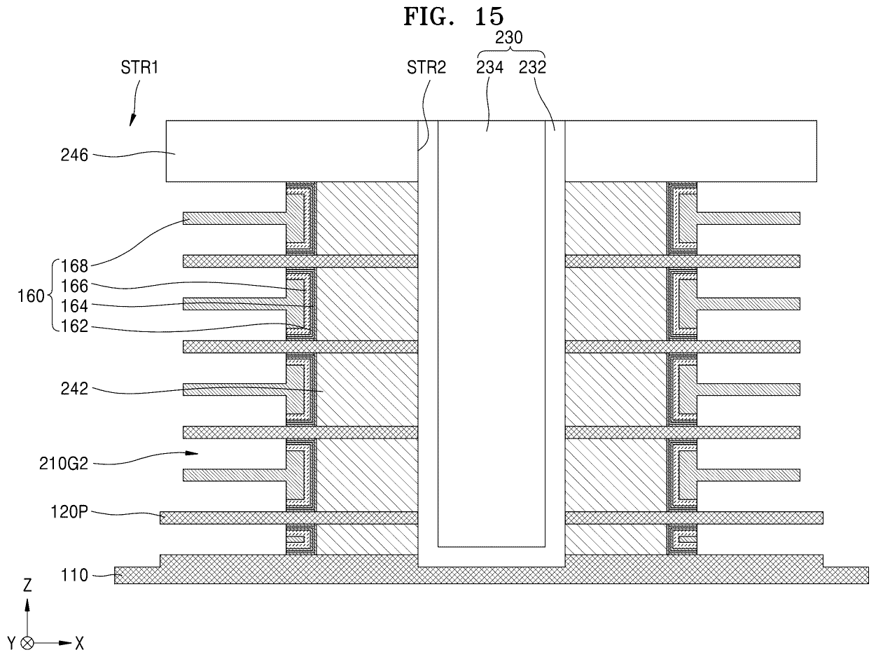

Referring to FIG. 15, in the resultant product of FIG. 14, a plurality of second gaps 210G2 may be formed by etching a portion of each of the liner insulating layer 162, the etch stop layer 164, the spacer liner layer 166, and the spacer embedded layer 168.

The liner insulating layer 162, the etch stop layer 164, the spacer liner layer 166, and the spacer embedded layer 168, which are partially removed, may be referred to as the separation insulating layer 160. The separation insulating layer 160 may electrically separate the word line 130 (see FIG. 17) formed in the subsequent process.

In some embodiments, the separation insulating layer 160 may be formed in a T shape rotated by 90° to include a pair of second gaps 210G2 between a pair of single crystal semiconductor layers 120P.

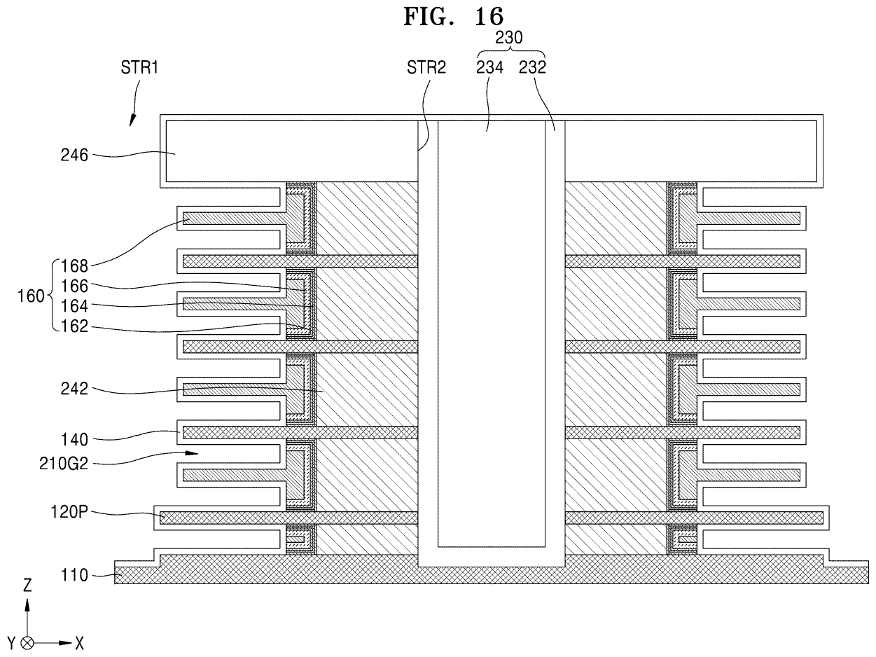

Referring to FIG. 16, the gate dielectric film 140 may be conformally formed on the exposed surface of the resultant product of FIG. 15.

The gate dielectric film 140 may include at least one selected from among silicon oxide, a high-k dielectric material having a dielectric constant greater than a dielectric constant of silicon oxide, and a ferroelectric material. In some embodiments, the gate dielectric film 140 may have a stack structure of a first dielectric film including silicon oxide and a second dielectric film including one from among a high-k dielectric material and a ferroelectric material.

Referring to FIG. 17, in the resultant product of FIG. 16, the plurality of word lines 130 may be formed to fill a partial space of the plurality of second gaps 210G2.

The plurality of word lines 130 may be formed such that, after forming a gate electrode material layer that covers the gate dielectric film 140 and fills the plurality of second gaps 210G2, a portion of the gate electrode material layer is removed so that the rest of the gate electrode material layer remains only on a partial space of the plurality of second gaps 210G2. In some embodiments, the word line 130 may include a conductive barrier film covering the gate dielectric film 140 and a conductive charge layer covering the conductive barrier film.

Next, the plurality of spacers 132 that fill the remaining space of the plurality of second gaps 210G2 may be formed in the vertical direction Z. In some embodiments, each of the plurality of spacers 132 may include silicon nitride. In some embodiments, some of the plurality of spacers 132 may cover the surface of the substrate 110 that is exposed at the bottom surface of the first recess STR1. A portion of the plurality of spacers 132 disposed on the substrate 110, as the bottom spacer 132L, may have a relatively great thickness.

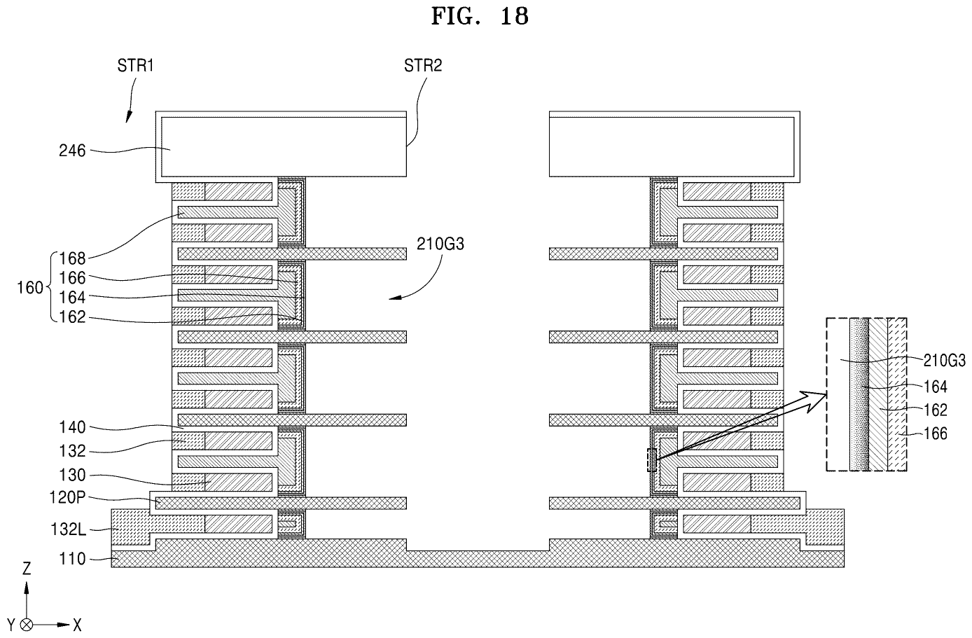

Referring to FIG. 18, in the resultant product of FIG. 17, the embedded structure 230 may be completed removed.

As the embedded structure 230 is removed, the remaining portion of the support sacrificial layer 242 may be exposed to the outside.

Next, the remaining portion of the support sacrificial layer 242 may be entirely removed in the first horizontal direction X, without a deviation between the upper and lower parts of the support sacrificial layer 242, by using the etch stop layer 164. For example, a process of removing the remaining portion of the support sacrificial layer 242 may be performed by a wet etching process using a chemical etchant. In this process, a portion of the liner insulating layer 162 that is exposed may be removed together. Accordingly, the side wall of the etch stop layer 164 may be exposed. A plurality of third gaps 210G3 may be formed.

In the wet etching process, as the liner insulating layer 162 located between the plurality of single crystal semiconductor layers 120P and the etch stop layer 164 has a quite thin thickness, the liner insulating layer 162 in this portion may not be used as a chemical pass through which the chemical etchant infiltrates. For example, the thickness of the liner insulating layer 162 located between the plurality of single crystal semiconductor layers 120P and the etch stop layer 164 may be about 20 Å to 60 Å, but embodiments of the present disclosure are not limited thereto.

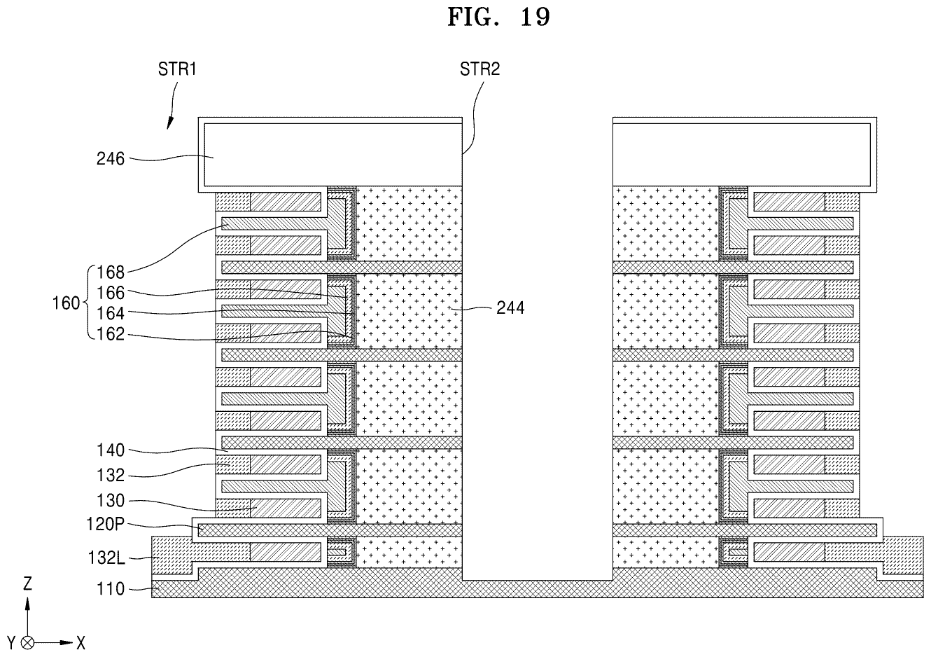

Referring to FIG. 19, in the resultant product of FIG. 18, a storage sacrificial layer 244 may be formed to fill the plurality of third gaps 210G3.

The storage sacrificial layer 244 may be formed to fill all of the plurality of third gaps 210G3 between the plurality of single crystal semiconductor layers 120P. However, end portions of the plurality of single crystal semiconductor layers 120P may be exposed to the outside.

In some embodiments, the storage sacrificial layer 244 may include any one selected from among a silicon carbide film, a carbon-containing silicon oxide film, a carbon-containing silicon nitride film, and a carbon-containing silicon oxynitride film.

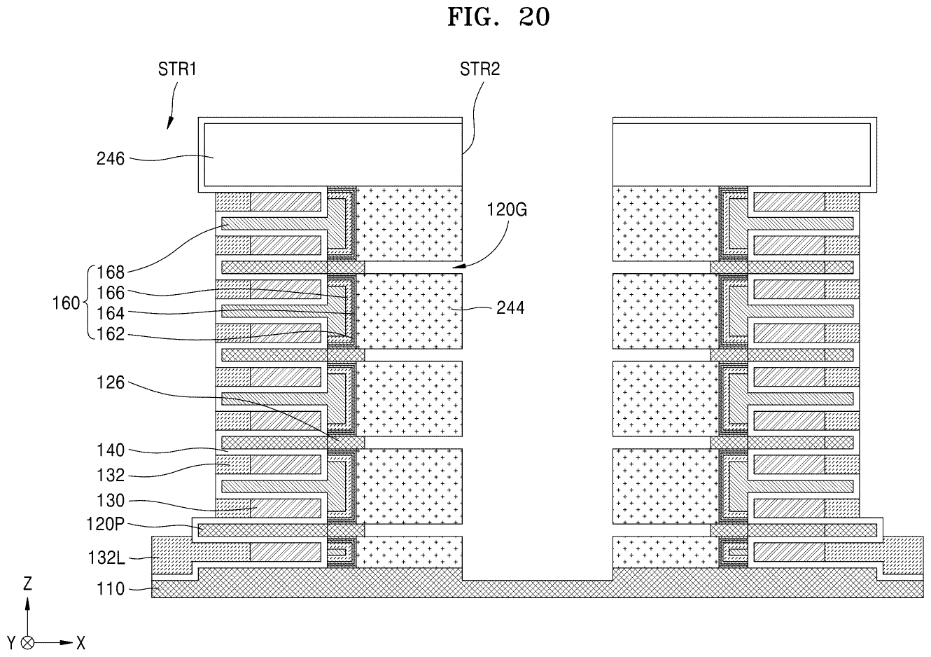

Referring to FIG. 20, in the resultant product of FIG. 19, a plurality of fourth gaps 120G may be formed by removing a portion of each of the plurality of single crystal semiconductor layers 120P in one lateral direction.

As the plurality of fourth gaps 120G are formed, the remaining portions of the plurality of single crystal semiconductor layers 120P may be arranged to be recessed inwardly from the plurality of storage sacrificial layers 244.

Next, the plurality of second source/drain regions 126 may be formed by injecting impurities into portions of the plurality of single crystal semiconductor layers 120P exposed through the plurality of fourth gaps 120G.

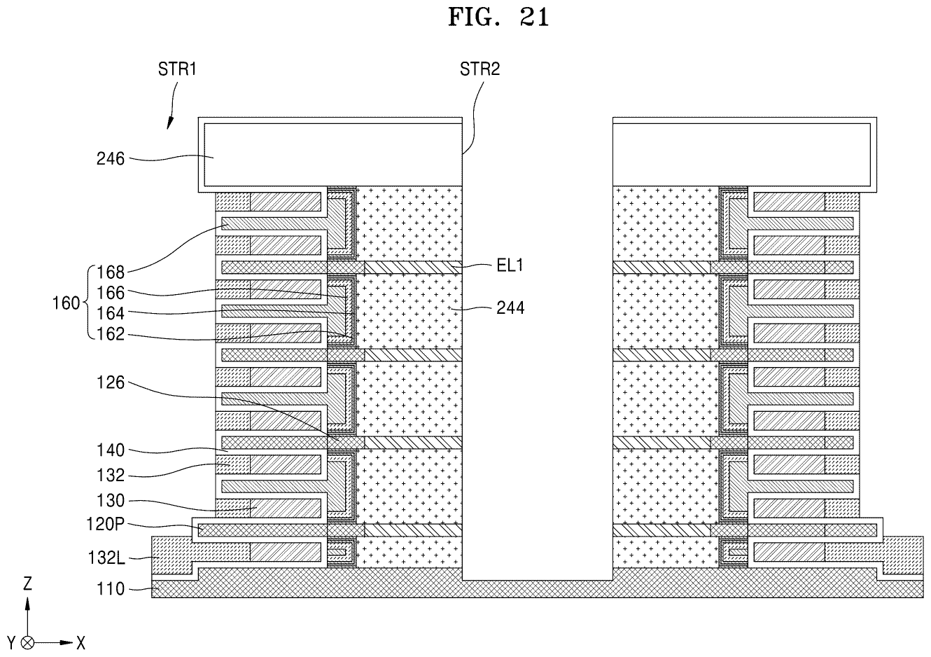

Referring to FIG. 21, in the resultant product of FIG. 20, the plurality of first electrodes EL1 may be formed to fill the plurality of fourth gaps 120G.

The plurality of first electrodes EL1 may be formed to fill all of the plurality of fourth gaps 120G so as to contact the plurality of second source/drain regions 126. However, end portions of the plurality of first electrodes EL1 may be exposed to the outside.

In some embodiments, each of the plurality of first electrodes EL1 may include: a doped semiconductor material; conductive metal nitride, such as titanium nitride, tantalum nitride, niobium nitride, tungsten nitride, etc.; metal, such as tungsten, ruthenium, iridium, titanium, tantalum, etc.; and conductive metal oxide, such as iridium oxide, niobium oxide, etc.

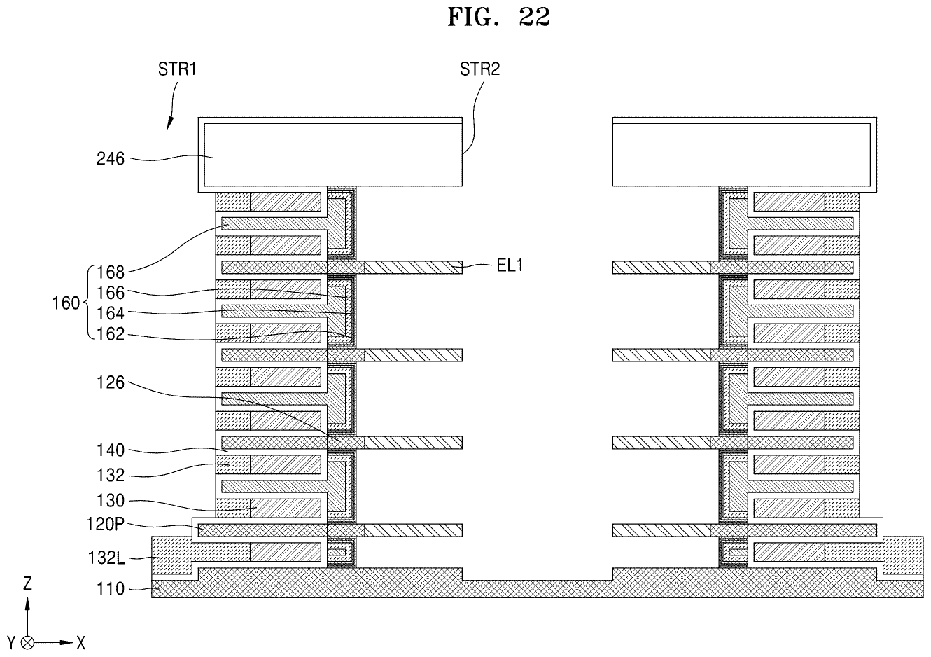

Referring to FIG. 22, in the resultant product of FIG. 21, the plurality of storage sacrificial layers 244 may be completely removed.

As the plurality of storage sacrificial layers 244 are removed, all portions of the plurality of first electrodes EL1 may be exposed to the outside. Furthermore, end portions of the plurality of second source/drain regions 126 may be exposed to the outside.

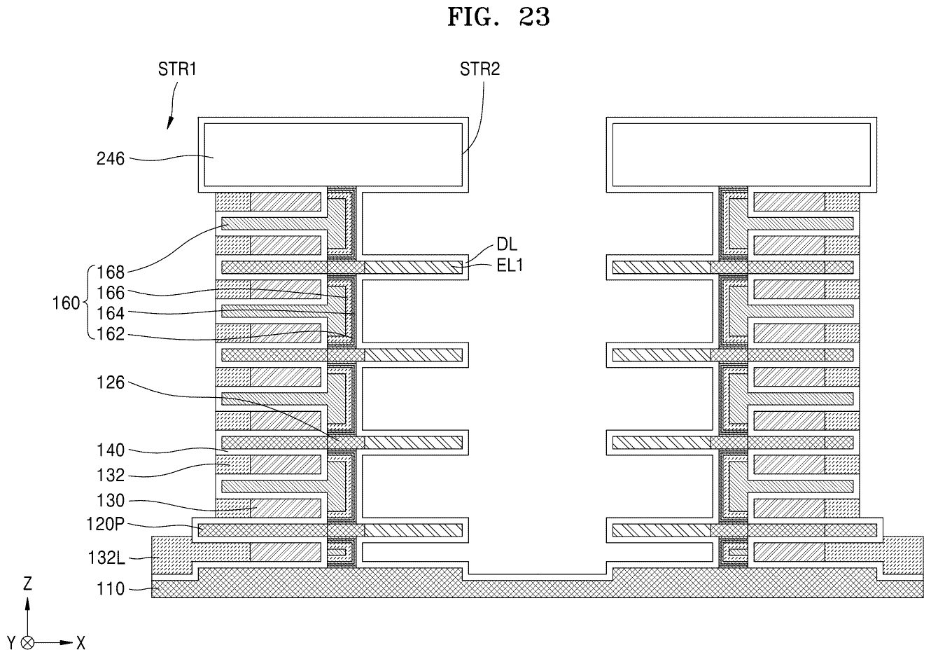

Referring to FIG. 23, in the resultant product of FIG. 22, the capacitor dielectric film DL may be conformally formed on the exposed surfaces of the plurality of first electrodes EL1 and the exposed surfaces of the plurality of second source/drain regions 126.

The capacitor dielectric film DL may include at least one selected from among silicon oxide, a high-k dielectric material having a dielectric constant greater than a dielectric constant of silicon oxide, and a ferroelectric material. In some embodiments, the capacitor dielectric film DL may have a stack structure of a first dielectric film including silicon oxide and a second dielectric film including one from among a high-k dielectric material and a ferroelectric material.

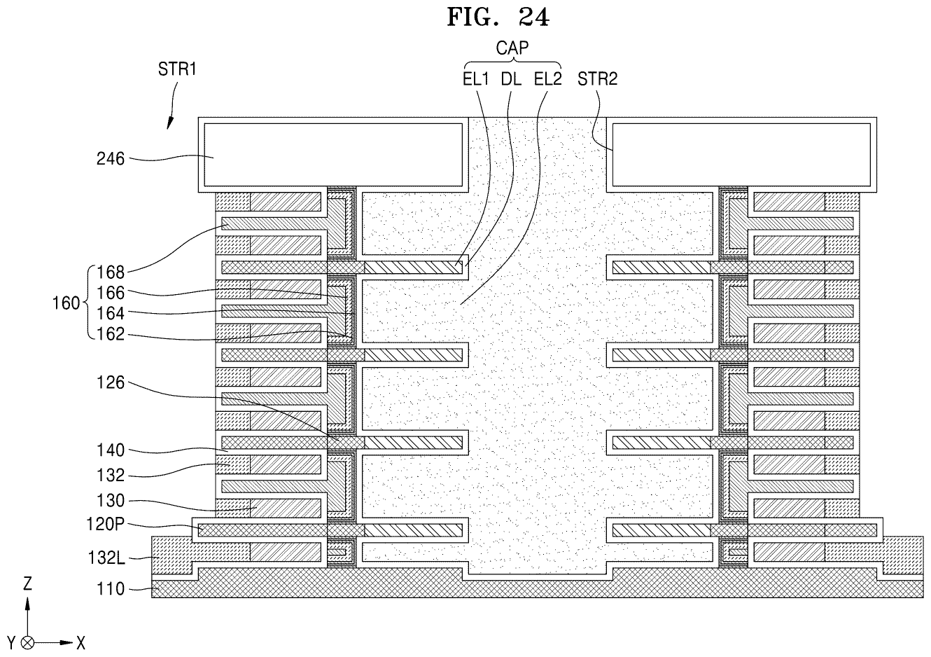

Referring to FIG. 24, in the resultant product of FIG. 23, the second electrode EL2 may be formed to fill space on the capacitor dielectric film DL.

In some embodiments, the second electrode EL2 may be formed to entirely fill the second recess STR2. In other words, the upper surface of the second electrode EL2 may be formed to a vertical level higher than a vertical level of the upper surface of the upper insulating layer 246.

In some embodiments, the second electrode EL2 may include: a doped semiconductor material; conductive metal nitride, such as titanium nitride, tantalum nitride, niobium nitride, tungsten nitride, etc.; metal, such as tungsten, ruthenium, iridium, titanium, tantalum, etc.; and conductive metal oxide, such as iridium oxide, niobium oxide, etc.

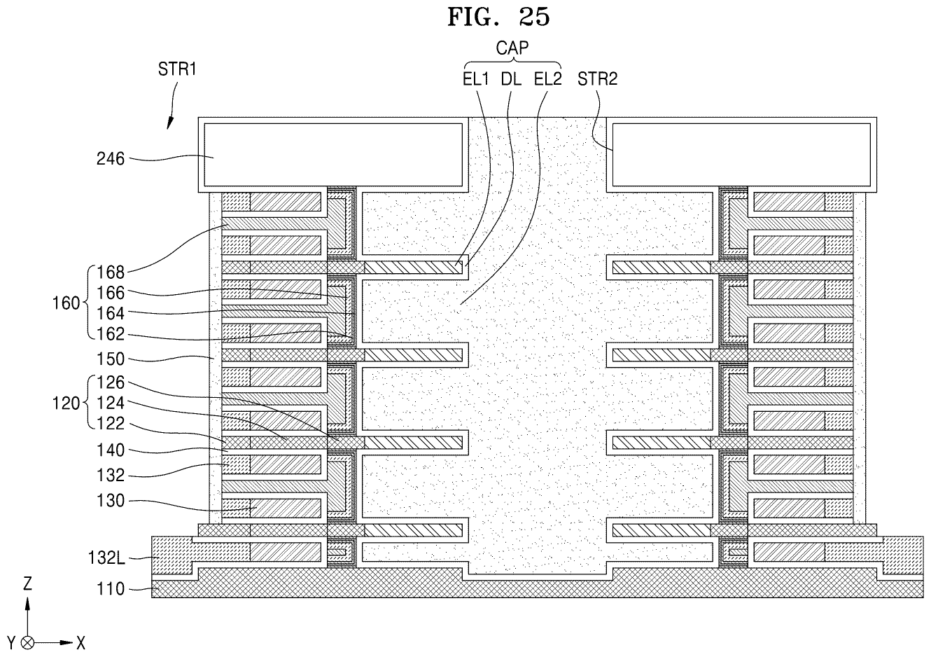

Referring to FIG. 25, in the resultant product of FIG. 24, portions of the plurality of spacers 132 and portions of the gate dielectric film 140, which are exposed through the first recess STR1, may be removed.

Portions of the plurality of single crystal semiconductor layers 120P towards first recess STR1 may be exposed. In some embodiments, the plurality of first source/drain regions 122 may be formed by injecting impurities into the portions of the plurality of single crystal semiconductor layers 120P exposed through the first recess STR1.

Accordingly, the plurality of single crystal semiconductor layers 120P may configure the plurality of transistor body portions 120. The plurality of transistor body portions 120 may include the first source/drain region 122, the single crystal channel layer 124, and the second source/drain region 126, which are arranged in order in the first horizontal direction X.

Next, the bit line 150 may be formed, which may be in contact with each of the plurality of first source/drain regions 122 and extends in the vertical direction Z within the first recess STR1. The first source/drain region 122 may be connected to the bit line 150, and the second source/drain region 126 may be connected to the first electrode EL1 of the cell capacitor CAP.

Referring back to FIG. 2, the bit-line insulating layer 152 may be formed around the bit line 150 to extend in the vertical direction Z, and the cover insulating layer 154 may be formed above the bit-line insulating layer 152 to cover each of the plurality of cell capacitors CAP.

By using a method of fabricating a semiconductor device described above, the semiconductor device 10 according to an embodiment may be fabricated.

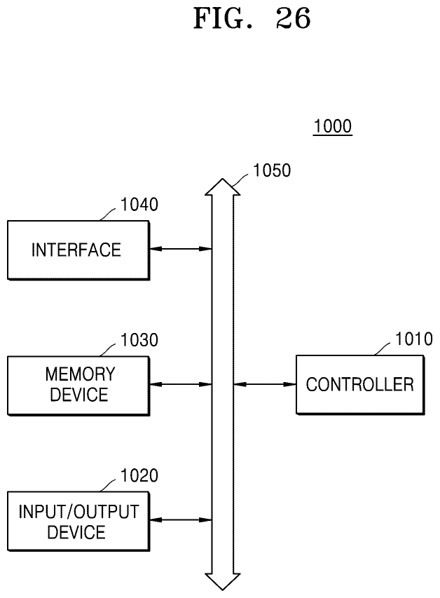

FIG. 26 is a configuration view illustrating a system 1000 including a semiconductor device according to an embodiment.

Referring to FIG. 26, the system 1000 may include a controller 1010, an input/output device 1020, a memory device 1030 (e.g., memory), an interface 1040, and a bus 1050.

The system 1000 may be a mobile system or a system for transmitting or receiving information. In some embodiments, the mobile system may be a portable computer, a web tablet, a mobile phone, a digital music player, or a memory card.

The controller 1010 may be configured for controlling an execution program on the system 1000, and may include a microprocessor, a digital signal processor, a microcontroller, or a similar device.

The input/output device 1020 may be used to input or output the data of the system 1000. The system 1000 may be connected to an external device such as, for example, a personal computer or a network, or exchange data with the external device, by using the input/output device 1020. The input/output device 1020 may include, for example, a touch screen, a touch pad, a keyboard, or a display.

The memory device 1030 may store data for the operation of the controller 1010 or data processed by the controller 1010. The memory device 1030 may include any one of the semiconductor devices 10, 10A, 10B, and 10C described above according to embodiments.

The interface 1040 may be a data transmission path between the system 1000 and the external device. The controller 1010, the input/output device 1020, the memory device 1030, and the interface 1040 may communicate with one another through the bus 1050.

While non-limiting example embodiments of the present disclosure have been described above with reference to the accompanying drawings, it will be understood that various changes in form and details may be made therein without departing from the spirit and scope of the present disclosure. Thus, the above-described embodiments are examples in all aspects and should not be for purposes of limitation.

What is claimed is:

1. A semiconductor device comprising:
a substrate;
a bit line extending in a vertical direction on the substrate;
a transistor body portion connected to the bit line and comprising a first source/drain region, a channel region, and a second source/drain region, which are arranged in the order of the first source/drain region, the channel region, and the second source/drain region in a first horizontal direction;
a word line extending in a second horizontal direction crossing the first horizontal direction, wherein the word line is on the channel region;
a gate dielectric film between the channel region and the word line;
a cell capacitor connected to the second source/drain region in the first horizontal direction and comprising a storage electrode, a capacitor dielectric film, and a plate electrode; and
an etch stop layer between the word line and the capacitor dielectric film, the etch stop layer contacting the capacitor dielectric film.

2. The semiconductor device of claim 1, further comprising a liner insulating layer between the etch stop layer and the transistor body portion, and
a material of the etch stop layer is different from a material of the liner insulating layer.

3. The semiconductor device of claim 2, further comprising an additional transistor body portion that includes an additional first source/drain region, an additional channel region, and an additional second source/drain region, which are arranged in the order of the additional first source/drain region, the additional channel region, and the additional second source/drain region in the first horizontal direction,
wherein the transistor body portion and the additional transistor body portion face each other in the vertical direction,
wherein at least a portion of the etch stop layer is extends lengthwise in the vertical direction between the transistor body portion and the additional transistor body portion, and
wherein the etch stop layer is in contact with the capacitor dielectric film and is spaced apart from the transistor body portion and the additional transistor body portion.

4. The semiconductor device of claim 3, further comprising:
an additional word line; and
an additional gate dielectric film;
wherein the word line and the additional word line are between the transistor body portion and the additional transistor body portion, and
wherein the etch stop layer is in contact with the gate dielectric film and the additional gate dielectric film.

5. The semiconductor device of claim 2, wherein the liner insulating layer is in contact with each of the transistor body portion, the etch stop layer, the capacitor dielectric film, and the gate dielectric film.

6. The semiconductor device of claim 5, wherein a side wall of the liner insulating layer is in contact with the capacitor dielectric film,
wherein a side wall of the etch stop layer is in contact with the capacitor dielectric film, and
wherein the side wall of the liner insulating layer and the side wall of the etch stop layer are coplanar with each other in the vertical direction.

7. The semiconductor device of claim 6, wherein the liner insulating layer comprises silicon oxide, and
wherein the etch stop layer comprises silicon nitride.

8. The semiconductor device of claim 7, wherein a concentration of nitrogen gradually varies in the silicon nitride of the etch stop layer.

9. The semiconductor device of claim 1, wherein the etch stop layer overlaps with the second source/drain region of the transistor body portion in the vertical direction.

10. The semiconductor device of claim 9, wherein the etch stop layer faces towards, and is spaced apart from, the transistor body portion in the vertical direction, and
wherein the etch stop layer faces and contacts the capacitor dielectric film in the first horizontal direction.

11. A semiconductor device comprising:
a bit line extending in a vertical direction on a substrate;
a pair of transistor body portions connected to the bit line and comprising a first source/drain region, a channel region, and a second source/drain region, which are arranged in the order of the first source/drain region, the channel region, and the second source/drain region in a first horizontal direction;
a pair of word lines extending in a second horizontal direction crossing the first horizontal direction, the pair of word lines being on the channel region between the pair of transistor body portions;
a pair of gate dielectric films between the pair of transistor body portions and the pair of word lines;
a cell capacitor connected to the second source/drain region in the first horizontal direction and comprising a storage electrode, a capacitor dielectric film, and a plate electrode;
a liner insulating layer that is on the pair of transistor body portions and the capacitor dielectric film, and
an etch stop layer that contacts the capacitor dielectric film.

12. The semiconductor device of claim 11, wherein the liner insulating layer comprises:
a first liner insulating layer on a first side of the etch stop layer; and
a second liner insulating layer on a second side of the etch stop layer, opposite of the first side.

13. The semiconductor device of claim 12, wherein the first liner insulating layer is in contact with each of a transistor body portion of the pair of transistor body portions, the etch stop layer, the capacitor dielectric film, and a gate dielectric film of the pair of gate dielectric films, and
wherein the second liner insulating layer is in contact with the etch stop layer and the gate dielectric film, and is spaced apart from the transistor body portion and the capacitor dielectric film.

14. The semiconductor device of claim 13, wherein a material of the etch stop layer is different from a material of the first liner insulating layer and a material of the second liner insulating layer.

15. The semiconductor device of claim 14, wherein the capacitor dielectric film is on the storage electrode, the etch stop layer, and the first liner insulating layer.

16. A semiconductor device comprising:
a substrate;
a bit line extending in a vertical direction on the substrate;
a transistor body portion connected to the bit line and comprising a first source/drain region, a channel region, and a second source/drain region, which are arranged in the order of the first source/drain region, the channel region, and the second source/drain region in a first horizontal direction;
a word line extending in a second horizontal direction crossing the first horizontal direction, wherein the word line is on the channel region;
a gate dielectric film between the channel region and the word line;
a cell capacitor connected to the second source/drain region in the first horizontal direction, and comprising a storage electrode, a capacitor dielectric film, and a plate electrode; and
at least one etch stop layer between the word line and the capacitor dielectric film and comprising an element having a concentration that gradually varies.

17. The semiconductor device of claim 16, wherein the at least one etch stop layer comprises silicon nitride, and
wherein the element of the at least one etch stop layer comprises nitrogen.

18. The semiconductor device of claim 17, wherein the at least one etch stop layer is formed by any one from among a mixed growth process, an annealing process, and a plasma process.

19. The semiconductor device of claim 18, wherein the at least one etch stop layer is a single etch stop layer.

20. The semiconductor device of claim 18, wherein the at least one etch stop layer comprises a plurality of etch stop layers.
